(19) United States
(12) Patent Application Publication
(10) Pub. No.: US 2025/0385171 A1
(43) Pub. Date: Dec. 18, 2025

(54) REDISTRIBUTION LAYERS WITH GROUND PAD EXTENSIONS TO SUPRESS CROSSTALK

(71) Applicant: NVIDIA Corporation, Santa Clara, CA (US)

(72) Inventor: Pezhman Monadgemi, Santa Clara, CA (US)

(21) Appl. No.: 18/744,200

(22) Filed: Jun. 14, 2024

(51) Int. Cl. H01L 23/498

(52) U.S. Cl. CPC H01L 23/49838; H01L 23/49822; H01L 23/49827; H01L 23/49816

(57) ABSTRACT

A semiconductor device with first and second portions of a redistribution layer with arrays of through via elements carrying electrical ground connections that includes one or more contact pads that have one or more extensions projecting therefrom into a null space between through via elements carrying electrical signals. A method of manufacturing the semiconductor device is also disclosed.

### TECHNICAL FIELD

This application is directed, in general, to semiconductor devices, and in particular, a redistribution layer of semiconductor devices, and, a method of manufacturing such devices.

### BACKGROUND

A redistribution layer (RDL) has electrically conductive lines (e.g., conductive planer layers or traces), and pads to facilitate directing electrical signals between the components of a semiconductor device. A signal traveling through a set of the conductive lines and contact pads (an aggressor line) can produce electromagnetic crosstalk that interferes with a different signal traveling through a different set of the conductive lines and pads (a victim line). To mitigate crosstalk, non-signal carrying conductive vias (e.g., ground or power through silicon via, TSV, or. through insulator via, TIV) can be positioned in between the aggressor and victim lines. But, the number ground vias that can be positioned between such signal lines is subject to the design rules for any particular semiconductor device, and adding more ground vias can limit the space available for signal-carrying lines in the RDL, which in turn, can limit the bandwidth of signal communication through the RDL.

### SUMMARY

One aspect provides a semiconductor device that includes a redistribution layer. The redistribution layer includes a first redistribution layer portion. The first redistribution layer portion includes a first array of through layer via TLV elements, the TLV elements connected to carry one of first electrical signals, an electrical ground connection or power voltage connection. The redistribution layer includes a second redistribution layer portion adjacent to the first redistribution layer portion. The second redistribution layer portion includes a second array of the TLV elements. The TLV elements of the second array are connected to carry one of second electrical signals, the power voltage connection or the electrical ground connection. For the TLV elements carrying the first electrical signals and the second electrical signals that are separated from each other by one or more of the TLV elements carrying the electrical ground connections, the one or more of the TLV elements carrying the electrical ground connections includes one or more contact pads that have one or more extensions projecting therefrom into a null space between the one or more of TLV elements carrying the electrical ground connections and the TLV elements carrying the first electrical signal or the second electrical signal.

In some embodiments, the redistribution layer is part of an interposer layer, a package substrate layer or a printed circuit board layer (PCB) of the semiconductor device.

In some embodiments, the semiconductor device includes a plurality of the redistribution layers.

In some embodiments, when the redistribution layer is an interposer layer or a package substrate layer, the one or more of the TLV elements carrying the electrical ground connections from device component contacts to the contact pads with the extensions contacting one or more of a front side dielectric layer a backside dielectric layer or a core layer of the interposer layer or the package substrate layer.

In some embodiments, when the redistribution layer is a PCB substrate layer, the one or more of the TLV elements carrying the electrical ground connections from backside contacts of an interposer layer or a package substrate layer to the contact pads with the extensions contacting one or more insulating layers of the PCB substrate layer.

In some embodiments, at least one of the one or more extensions are aligned with a circumference that is a λ/8 radial distance away from the aggressor signal carrying TLV element or the victim signal receiving element, where λ is a signal wavelength given by the formula:

$$λ = 300 / ( F \times ( ε R ) 1 / 2 )$$

where F equals a frequency of signal transmission from the aggressor signal carrying TLV element and εR equals an average dielectric constant (εR) of the RDL. In some such embodiments, the λ/8 radial distance equals 375, 125, or 62.5 μm when the F value equals 50, 150, or 300 GHz, respectively, and the εR value equals 4.

In some embodiments, a length of the extension is such that a tip of the extension is centered in the null space.

In some embodiments, a width of the extension is equal to or less than a diameter of the contact pad that the extension projects from In some embodiments, a thickness of the extension is equal to or less than a thickness of an insulating layer of the RDL that the contact pad is located in.

In some embodiments, the semiconductor device is part of a computer having one or more electrical circuits that includes the redistribution layer of the semiconductor device

Another aspect provides a method of manufacturing a semiconductor device. The method includes providing a first redistribution layer portion and forming a first array of through layer via TLV elements in the first redistribution layer portion, the TLV elements of the first redistribution layer portion arranged to carry one of first electrical signals, a power voltage connection or an electrical ground connection. The method also includes providing a second redistribution layer portion adjacent to the first redistribution layer, and forming a second array of the TLV elements in the second redistribution layer portion, the TLV elements of the second redistribution layer portion arranged to carry one of second electrical signals, the power voltage connection or the electrical ground connection, For the TLV elements carrying the first electrical signals and the second electrical signals that are separated from each other by one or more of the TLV elements carrying the electrical ground connections, the forming of the first array and the forming of the second array includes forming one or more contact pads to have one or more extensions projecting therefrom into a null space between the one or more of TLV elements carrying the electrical ground connections and the TLV elements carrying the first electrical signal or the second electrical signal.

In some embodiments, the redistribution layer is part of an interposer layer, a package substrate layer or a printed circuit board layer of the semiconductor device.

In some embodiments, forming the redistribution layer includes forming a plurality of the redistribution layers.

In some embodiments, when the redistribution layer is an interposer layer or a package substrate layer, the one or more of the TLV elements carrying the electrical ground connections from device component contacts to the contact pads with the extensions contacting one or more of a front side dielectric layer a backside dielectric layer or a core layer of the interposer layer or the package substrate layer.

In some embodiments, when the redistribution layer is a PCB substrate layer, the one or more of the TLV elements carrying the electrical ground connections from backside contacts of an interposer layer or a package substrate layer to the contact pads with the extensions contacting one or more insulating layers of the PCB substrate layer.

In some embodiments, forming the extension includes forming the extension to be aligned with a circumference that is a λ/8 radial distance away from an aggressor signal carrying TLV element or a victim signal receiving element, wherein λ is given by the formula:

$$λ = 300 / ( F \times ( ε R ) 1 / 2 )$$

where F equals a frequency of signal transmission from the aggressor signal carrying TLV element and εR equals an average dielectric constant of the redistribution layer.

In some embodiments, forming of the extension includes forming the extension to have a length such that a tip of the extension that is centered in the null space.

In some embodiments, forming of the extension includes forming the extension to have a width that is equal to or less than a diameter of the contact pad that the extension projects from.

In some embodiments, forming of the extension includes forming the extension to have a thickness that is equal to or less than a thickness of a insulating layer of the RDL that the contact pad is located in.

### BRIEF DESCRIPTION OF FIGURES

Reference is now made to the following descriptions taken in conjunction with the accompanying drawings, in which:

FIG. 1 presents a plan view of an example embodiment of a semiconductor device of the disclosure;

FIG. 2 presents cross-sectional view of another example embodiment of the semiconductor device of the disclosure analogous to the device shown in FIG. 1, along view line 2-2 as shown in FIG. 1;

FIG. 3 presents a detailed perspective view of portions of a die and RDL of an example embodiment of the semiconductor device of the disclosure, analogous to the device shown in FIG. 2, corresponding to view 3 as shown in FIG. 2;

FIGS. 4a-4c present plan views of embodiments of an example contact array of an RDL of the semiconductor device corresponding to view 4 as shown in FIG. 3;

FIG. 5a presents a detailed cross-sectional view of example die and RDL portions of an embodiment of the semiconductor device, analogous to the device shown in FIG. 1, along view line 5a-5a as shown in FIG. 4b;

FIGS. 5b and 5c present a detailed cross-sectional views of example RDL portions of embodiments of semiconductor device, analogous to the device shown in FIG. 1, along view line 5b-5b in FIG. 4b;

FIG. 6 presents a block diagram of a computer having one or more circuits that include any embodiments of the semiconductor device such as disclosed in the context of FIGS. 1-5c; and

FIG. 7 presents a flow diagram of a method of manufacturing the semiconductor device including any embodiments of the device disclosed in the context of FIGS. 1-6.

### DETAILED DESCRIPTION

Embodiments of the disclosure follow from my idea that the suppression of electromagnetic cross-talk can be facilitated by altering the structure of ground contact pads present in through RDL vias (e.g., ground-carrying TLVs or ground TLV elements), to include extension structures (“extensions”) that serve to reduce the resistance of the ground pad, and hence reduce the resistance of the TLV element, without breaking the semiconductor device's form factor design rules. This is in contrast to attempting to place more ground lines, vias and contact pads in the RDL and thereby reducing the density of signal carrying lines available in the RDL.

I recognized that the signal aggressor line carried by a TLV via (e.g., aggressor signal transmitting TLV elements) acts as an antenna, broadcasting potential electromagnetic cross-talk that can be received by the victim line (e.g., a victim signal receiving TLV element). For a given frequency (F) of signal transmission (e.g., F equal to 50, 150, 300 GHz) and dielectric constant (ε_{R}) of the RDL (e.g., ε_{R}=4 for some embodiments), the crosstalk signal from the aggressor line will broadcast at a wavelength (λ) given by the formula: 300/(F×(ε_{R})^{1/2}) (e.g., λ equal to 3, 1 0.5 mm, or equivalently, 3000, 1000, 500 μm, respectively). Placing the ground pad extensions at a distance in a circumference that is radial distance of about λ/8 away from the aggressor signal carrying TLV element and/or victim signal receiving TLV element (e.g., λ/8 distance equal to 375, 125, 62.5 μm, respectively) is predicted to optimally suppress the cross talk transmission (e.g., near-end coupling) of the aggressor signal transmitting TLV element to the victim signal receiving TLV element.

As further illustrated in the example embodiments disclosed herein, to reduce the resistance of the ground pad, the ground pad extensions can have a variety of shapes and sizes and one or more of the extensions can be added to one or more ground pads, in different layers of the RDL, for each individual ground TLV elements, or for multiple ground TLV elements, that are located between signal carrying TLV elements of the RDL.

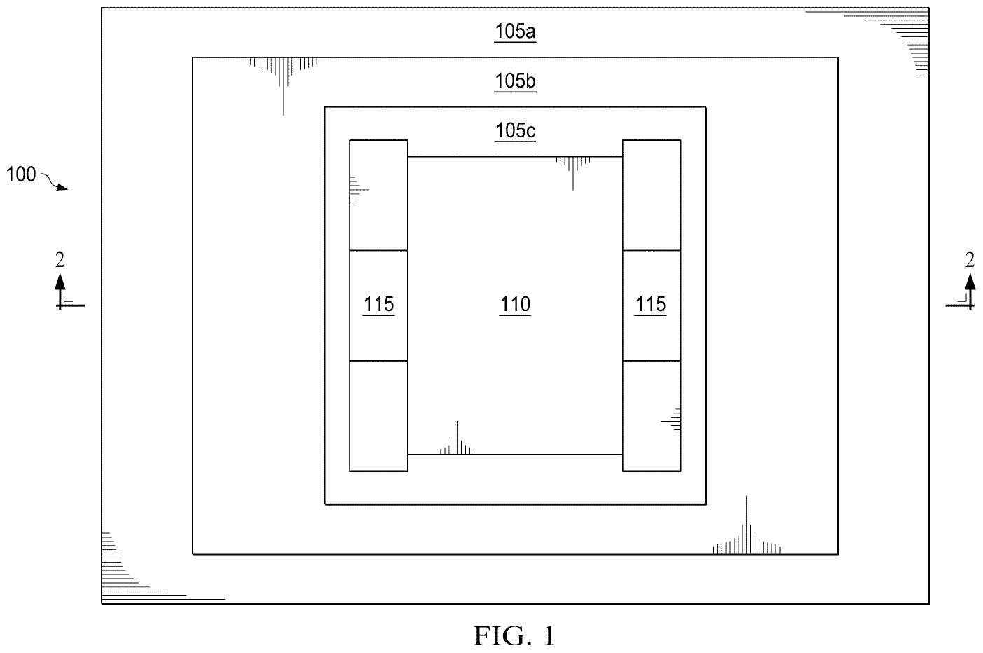

One embodiment of the disclosure is semiconductor device. FIGS. 1-5c present various embodiments of example semiconductor devices 100 of the disclosure that can include one or more RDLs 105a, 105b, 105c having ground-carrying TLV elements with a contact pad extension.

With continuation references to FIGS. 1-5c throughout, embodiments of the semiconductor device 100 include an RDL (generally 105). The RDL 105 can include a first RDL portion 305a and a second RDL portion 305b adjacent to the first RDL portion 305a.

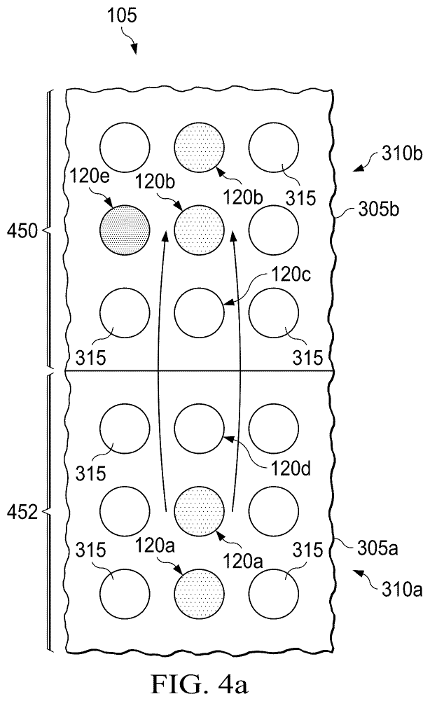

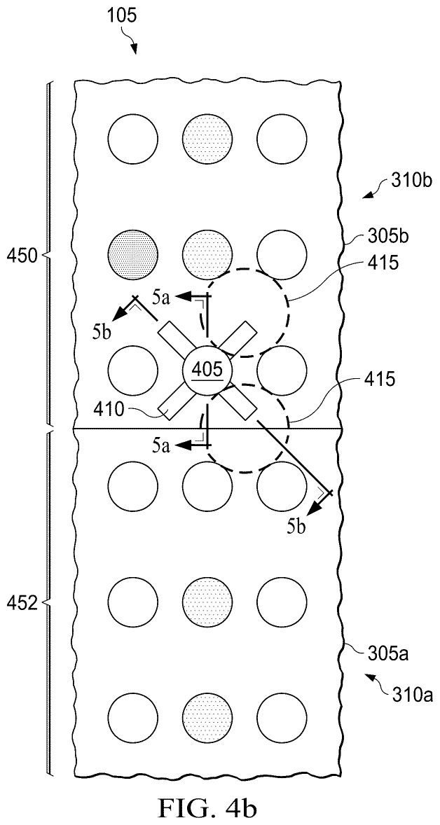

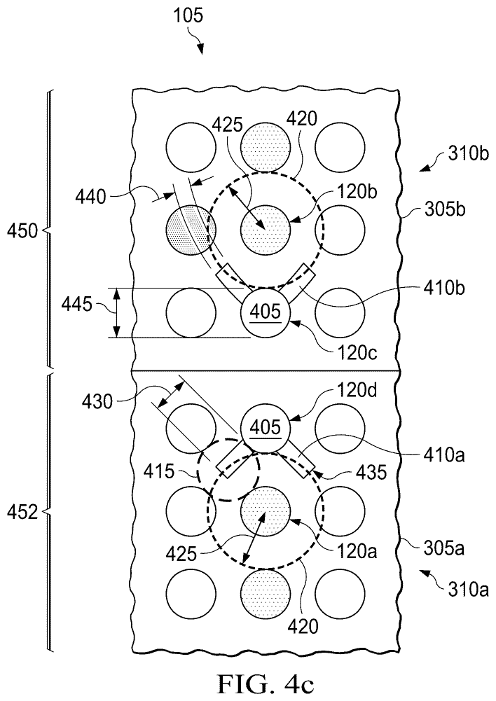

The first RDL portion 305a includes a first array 310a of through layer via TLV elements (generally 120) and the TLV elements can be connected to carry one of first electrical signals (e.g., TLV 120a carrying first signal; FIG. 4a), an electrical ground connection (e.g., TLV 120c carrying ground; FIG. 4a) or a power voltage connection.

The second RDL portion 305b includes a second array 310b of through layer via TLV elements and the TLV elements can be connected to carry one of second electrical signals (e.g., TLV 120b carrying second signal; FIG. 4a), an electrical ground connection (e.g., TLV 120c carrying ground; FIG. 4a) or a power voltage connection (e.g., TLV 120e carrying power voltage; FIG. 4a).

For the TLV elements carrying the first electrical signals (e.g., TLV 120a) and the second electrical signals (e.g., TLV 120b) that are separated from each other by one or more of the TLV elements carrying the electrical ground connections (e.g., TLVs 120c, 120), the one or more of the TLVs carrying the electrical ground connections includes one or more contact pads (generally contact pad 315, FIG. 4a). The one or more contact pads can have one or more extensions (e.g., contact pad 405 with extensions 410; FIGS. 4b-4c) projecting therefrom into a null space (e.g., null spaces 415; FIGS. 4b-4c) between the one or more of TLV elements carrying the electrical ground connections and the TLV elements carrying the first electrical signal or the second electrical signal.

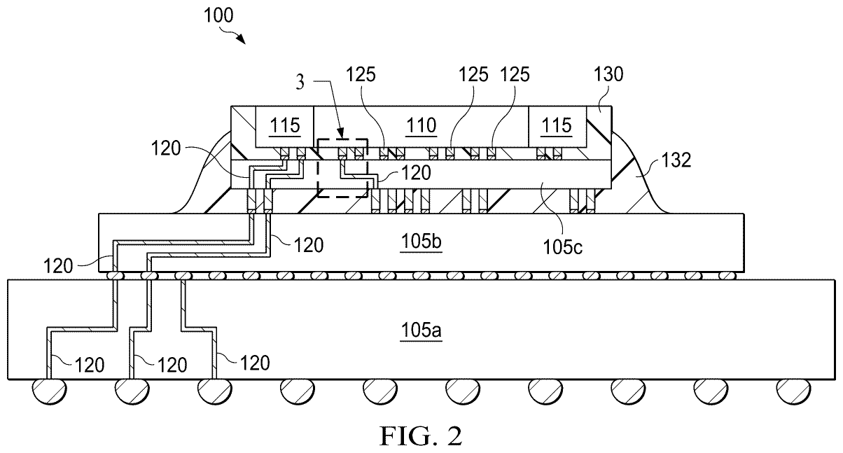

The term, RDL, as used herein, refers any insulating redistribution layer (e.g., inorganic material layers such as silicon nitride or silicon dioxide, or organic polymer layers such as epoxy polymer layers, or combinations thereof) including one or more layers with conductive lines and contact pads (e.g., metal lines, pads and vias, such as copper lines, pads and vias) therein or thereon, to direct electrical signals, power, and ground connections between the components of a semiconductor device. E.g., the RDL can be an interposer (e.g., interposer RDL 105c; FIGS. 1-2), a package substrate (e.g., package substrate RDL 105b; FIGS. 1-2) such as used in a multi-chip module MCM devices, or, printed circuit board substrate (e.g., PCB substrate RDL 105a; FIGS. 1-2), and the semiconductor device can include multiple embodiments of such RDLs.

The term TLV as used herein refers to through-silicon vias inside silicon interposers (TSV) or through interposer via (TIV) or combinations thereof.

The term device component 110 as used herein, refers to any physical layer (PHY) such as a low frequency interface, such as General-Purpose Input/Output (GPIO), Joint Test Action Group (JTAG), or, a high-frequency interface such as Display, Graphic Processing Unit (GPU) to high bandwidth memory (HBM), Central Processing Unit (CPU) to HBM, semiconductor die-to-die structures (e.g., GPU to GPU, CPU to CPU, GPU to CPU etc.) or Peripheral Component Interconnect Express (PCIe) structures, or combinations thereof.

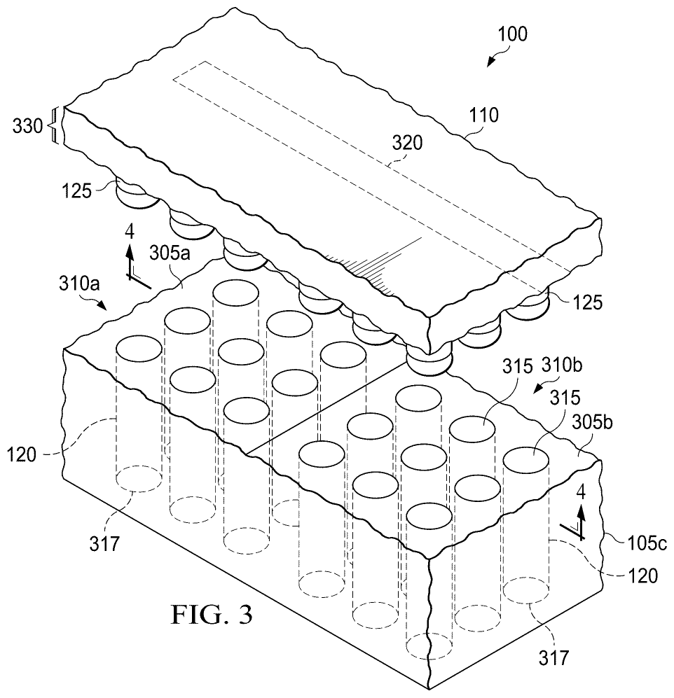

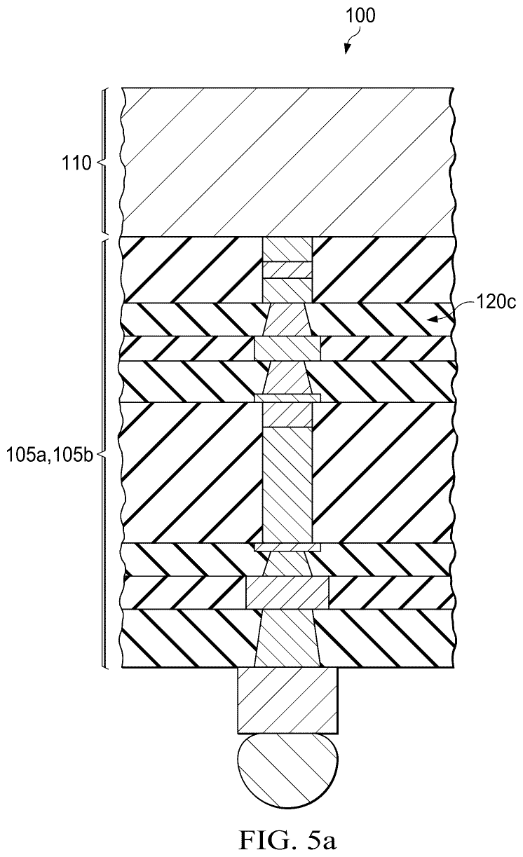

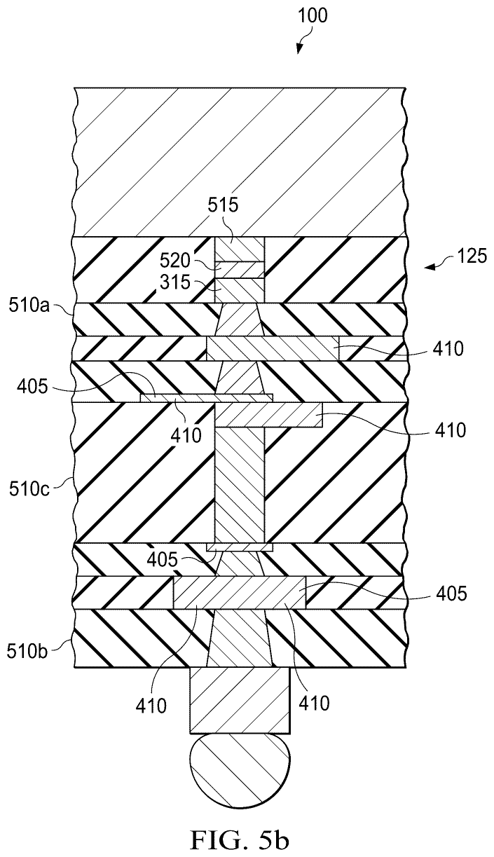

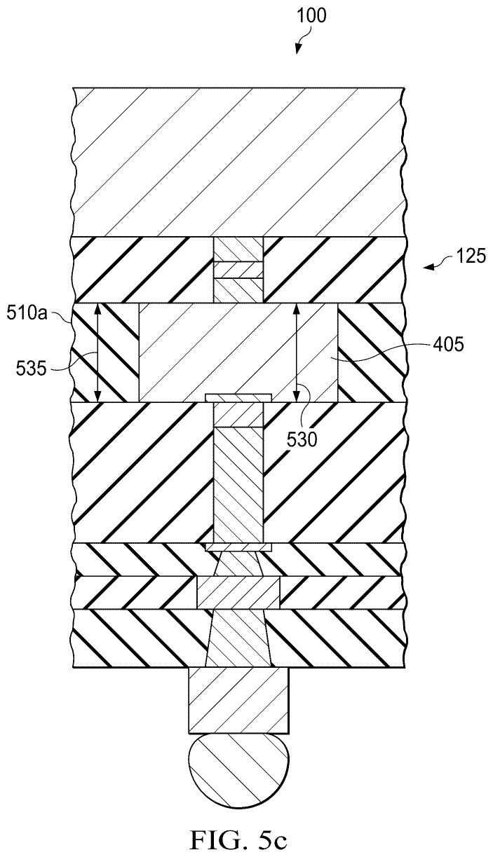

A device component contact 125 can include contact pads 515 of the device component and solder bumps 520 to facilitate electrical connection to frontside or backside surface contact pads 315, 317 of the RDL (e.g., FIGS. 3, 5a-5c).

Non-limiting examples of semiconductor devices having one or more such RDLs with the extension include, Multi-chip package (MCP), Fan-out wafer-level package (FOWLP), Chip-on-wafer-on-substrate (CoWoS), Silicon Wafer Integrated Fan-out Technology (SWIFT), Fan-Out chip-on-substrate (FoCoS), or other single or multiple die system-on-chip (SoC) devices as familiar to those skilled in the pertinent arts. Any such devices can include decoupling capacitors to help decouple a power supply from electromagnetic noise.

In some embodiments of the semiconductor device 100, the RDL with the extension can be part of an interposer layer 105c, a package substrate layer 105b or a printed circuit board layer 105a of the semiconductor device 100, or combinations thereof. For instance, some embodiments of the semiconductor device 100 can include a plurality of the RDLs 105a, 105b, 105c.

In some embodiments, when the RDL is an interposer layer 105c or a package substrate layer 105b, then the one or more of the TLV elements carrying the electrical ground connections (e.g., TLVs 120c, 120d) can be from device component contacts 125 to the contact pads 315, 405, with the extensions 410 contacting one or more of a front side dielectric layer 510a a backside dielectric layer 510b or a core layer 510c of the interposer layer or the package substrate layer (FIGS. 5a-5c).

In analogous fashion, in some embodiments, when the redistribution layer is an PCB substrate layer 105a, then the one or more of the TLV elements carrying the electrical ground connections (e.g., TLVs 120c, 120d) can be from backside contacts 317 of an interposer layer 105c or a package substrate layer 105b to the contact pads 315, 405 with the extensions 410 contacting one or more insulating layers of the PCB substrate layer.

In some embodiments, at least one of the one or more extensions 410 are aligned with a circumference 420 that is a λ/8 radial distance 425 away from the aggressor signal carrying TLV element 120a or the victim signal receiving element 120b (FUG. 4c). In such embodiments, λ, the signal wavelength, is given by the formula:

$$λ = 300 / ( F \times ( {ε}_{R} ) 1 / 2 )$$

where F equals a frequency of signal transmission from the aggressor signal carrying TLV element 120a and εR equals an average dielectric constant (εR) of the RDL.

In some embodiments, the extensions can be rectangular-shaped extensions in the plan view shown in FIGS. 4a-4c; e.g., FIG. 4c, extension 410a). However, in other embodiments, the extensions can be arc-shaped extensions (e.g., FIG. 4c, extension 410b) so as to more precisely align with the λ/8 radial 425 distance of the circumference 420 and thereby better suppress cross-talking coupling.

As non-limiting examples, in some embodiments the λ/8 radial distance 425 equals 375, 125, or 62.5 μm when the F value equals 50, 150, or 300 GHz, respectively, and the ε_{R} value equals 4.

In some embodiments, a length of the extension 410 can be such that a tip of the extension 410 is centered in the null space 415 (e.g., length 430, tip 435; FIG. 4c). E.g., the tip can be equi-distance from the surrounding contact pads of the ground carrying TLV element (e.g., TLVs 120c, 120a).

Based on the present disclosure one skilled in the pertinent art would understand how the size of the null space between adjacent or nearest neighbor TLVs elements would be defined by the specific form factor rules for a device, such as the minimum allowable bump pitch between TLVs (e.g., 200, 150, 100, 75 μM in some embodiments) and the layout of the array of TLVs for a particular device embodiment.

In some embodiments, e.g., to facilitate reducing the electrical resistance of the ground carrying TLV elements, a width of the extension 410 can be equal to or less than a diameter of the contact pad 405 that the extension projects from (e.g., width 440 equal to 1/10, ¼ ½ 1 of the extension diameter 445; FIG. 4c).

In some embodiments, e.g., to facilitate reducing the electrical resistance of the ground carrying TLV elements, a thickness of the extension 410 can be equal to or less than a thickness of an insulating of the RDL 105 that the contact pad 405 is located in layer (e.g., thickness 530 equal to thickness 535 of insulating layer 510a; FIGS. 5c)

Any of the device embodiments can include one or more mold compound layers (e.g., layers 130, 132, such as epoxy, silicon dioxide filler layers or combinations thereof), as familiar to those skilled in the pertinent arts. Any of the device embodiments can include one or more clock conductive lines (e.g., FIG. 3, clock line 320) of the device component 110. As familiar to those skilled in the art, in some embodiments, the clock lines can be shared by different portions of the device component 110 to facilitate sharing the same clock cycle. In some such embodiments, portions (FIGS. 4a-4c, RDL portions 450, 452) of the adjacent first and second redistribution layer portions 305a, 305b can be below the clock line 320 of the device component 110. In some such embodiments, the clock line 320 and device component contacts 125 are located in a peripheral region of the device component 110 referred to as a pad ring 330 (FIG. 3).

Any embodiments of the semiconductor device as disclosed herein can be part of a computer having one or more electrical circuits that include of the semiconductor device.

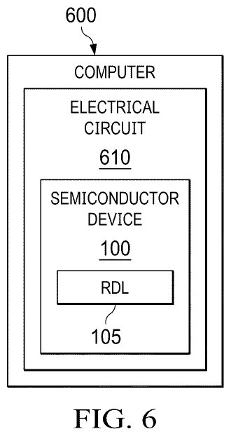

For example FIG. 6 presents a block diagram of a computer 600 having one or more electrical circuits 610 that can include any embodiments of the semiconductor device 100 having any embodiments of the RDL (e.g., one or more of RDLS 105a, 105b, 105c) having ground carrying TLV elements with the contact pad extensions such as disclosed in the context of FIGS. 1-5c, or, the device's method of manufacture, as disclosed herein.

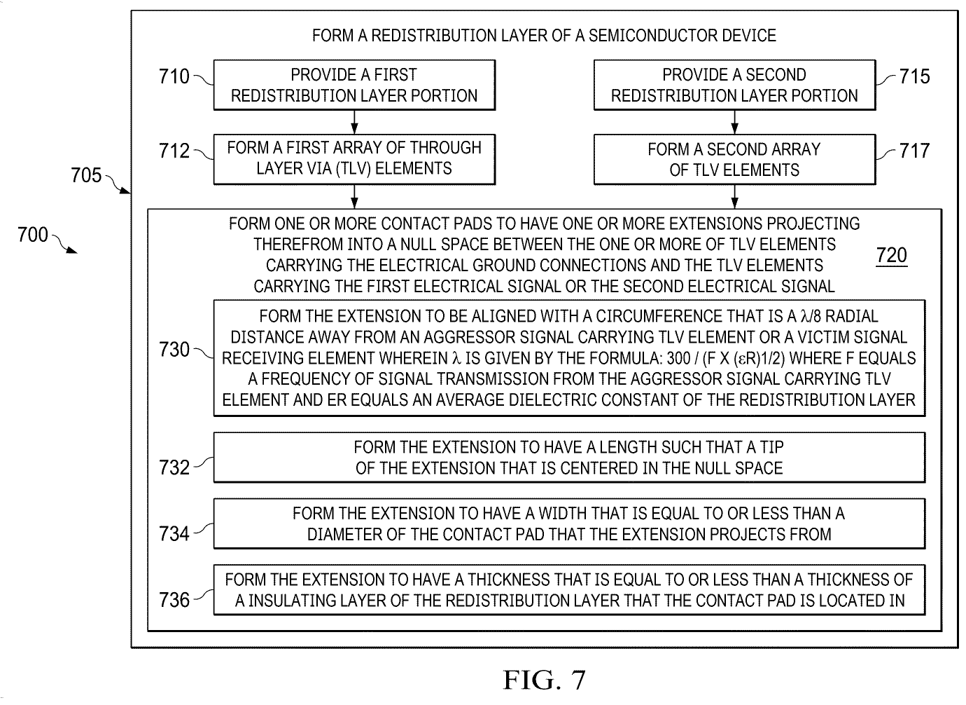

Another embodiment of the disclosure is a method of method of manufacturing a semiconductor device. FIG. 7 presents and example flow diagram of a method 700 of manufacturing a semiconductor device, such as any of the example semiconductor devices 100 embodiments disclosed in the context of FIGS. 1-6.

With continuing reference to FIGS. 1-7 throughout, the method includes forming 705 a RDL of the semiconductor device 100 (step 705). Those skilled in the pertinent art would be familiar with how to form RDL layers using conventional dielectric layer, metal layer deposition and patterning techniques.

Forming the RDL (step 705) includes providing 710 a first RDL portion 305a (step 710) and forming 712 a first array 310a of through layer via TLV elements (step 712) in the first RDL portion, e.g., such as set by the device's design rules. The TLV elements of the first RDL portion are arranged to carry one of first electrical signals (e.g., TLV 120a), a power voltage connection (e.g., TLV 120e) or an electrical ground connection (e.g., TLV 120c).

Forming the RDL (step 705) includes providing a second RDL portion 305b adjacent to the first RDL, (step 715) and forming a second array 310b of the TLV elements in the second RDL portion (step 717), the TLV elements of the second RDL portion arranged to carry one of second electrical signals (e.g., TLV 120b), the power voltage connection (e.g., TLV 120e) or the electrical ground connection (e.g., TLV 120d).

For the TLV elements carrying the first electrical signals and the second electrical signals (e.g., TLVs 120a, 120b) that are separated from each other by one or more of the TLV elements carrying the electrical ground connections (e.g., TLVs 120c, 120d), the forming of the first array 310a (step 712) and the forming the second array (step 717) includes forming (step 720) one or more contact pads (generally 315, 405) to have one or more extensions 410 projecting therefrom into a null space 415 between the one or more of TLV elements carrying the electrical ground connections and the TLV elements carrying the first electrical signal or the second electrical signal.

The RDL formed in step 705 can be part of an interposer layer 105c, a package substrate layer 105b or a printed circuit board layer 105a of the semiconductor device 100. The RDL formed in step 705 can include forming a plurality of the redistribution layers 105a, 105b, 105c.

When the RDL formed in step 705 is an interposer layer 105c or a package substrate layer 105b, the one or more of the TLV elements carrying the electrical ground connections (120c, 120d) from device component contacts 125 to the contact pads 315, 405 with the extensions 410 contacting one or more of a front side dielectric layer 510a a backside dielectric layer 510b or a core layer 510c of the interposer layer or the package substrate layer.

When the RDL formed in step 705 is an PCB substrate layer 105a, the one or more of the TLV elements carrying the electrical ground connections (120c, 120d) from backside contacts 317 of an interposer layer 105c or a package substrate layer 105b to the contact pads 315, 405 with the extensions 410 contacting one or more insulating layers of the PCB substrate layer.

In some embodiments, forming the contact pads extensions 410 in step 720 can include forming the extension (step 730) to be aligned with a circumference 420 that is a λ/8 radial distance 425 away from an aggressor signal carrying TLV element 120a or a victim signal receiving element 120b, wherein λ is given by the formula: 300/(F×(εR)^{1/2}), where F equals a frequency of signal transmission from the aggressor signal carrying TLV element 120a and εR equals an average dielectric constant of the redistribution layer.

In some embodiments, forming the contact pads extensions 410 in step 720 can include forming the extension (step 734) to have a width 440 that is equal to or less than a diameter 445 of the contact pad 405 that the extension projects from.

In some embodiments, forming contact pads extensions 410 in step 720 includes forming the extension (step 736) to have a thickness 530 that is equal to or less than a thickness 535 of a insulating layer (e.g., layer 510a) of the RDL 105 that the contact pad 405 is located in

Those skilled in the art to which this application relates will appreciate that other and further additions, deletions, substitutions and modifications may be made to the described embodiments.

What is claimed is:

1. A semiconductor device, comprising:
a redistribution layer including:
a first redistribution layer portion, the first redistribution layer portion including a first array of through layer via TLV elements, the TLV elements connected to carry one of first electrical signals, an electrical ground connection or power voltage connection or;
a second redistribution layer portion adjacent to the first redistribution layer portion, the second redistribution layer portion including a second array of the TLV elements, wherein the TLV elements of the second array are connected to carry one of second electrical signals, the power voltage connection or the electrical ground connection, and wherein:
for the TLV elements carrying the first electrical signals and the second electrical signals that are separated from each other by one or more of the TLV elements carrying the electrical ground connections, the one or more of the TLVs carrying the electrical ground connections includes one or more contact pads that have one or more extensions projecting therefrom into a null space between the one or more of TLV elements carrying the electrical ground connections and the TLV elements carrying the first electrical signal or the second electrical signal.

2. The device of claim 1, wherein the redistribution layer is part of an interposer layer, a package substrate layer or a printed circuit board layer of the semiconductor device.

3. The device of claim 1, wherein the semiconductor device includes a plurality of the redistribution layers.

4. The device of claim 1, when the redistribution layer is an interposer layer or a package substrate layer, the one or more of the TLV elements carrying the electrical ground connections from device component contacts to the contact pads with the extensions contacting one or more of a front side dielectric layer a backside dielectric layer or a core layer of the interposer layer or the package substrate layer.

5. The device of claim 1, when the redistribution layer is a PCB substrate layer, the one or more of the TLV elements carrying the electrical ground connections from backside contacts of an interposer layer or a package substrate layer to the contact pads with the extensions contacting one or more insulating layers of the PCB substrate layer.

6. The device of claim 1, wherein at least one of the one or more extensions are aligned with a circumference that is a λ/8 radial distance away from the aggressor signal carrying TLV element or the victim signal receiving element, where a signal wavelength, λ, is given by the formula:
$$λ = 300 / ( F \times ( {ε}_{R} ) 1 / 2 )$$
where F equals a frequency of signal transmission from the aggressor signal carrying TLV element and εR equals an average dielectric constant (εR) of the RDL.

7. The device of claim 6, wherein the λ/8 radial distance equals 375, 125, or 62.5 μm when the F value equals 50, 150, or 300 GHz, respectively, and the ε_{R} value equals 4.

8. The device of claim 1, wherein a length of the extension is such that a tip of the extension is centered in the null space.

9. The device of claim 1, wherein a width of the extension is equal to or less than a diameter of the contact pad that the extension projects from.

10. The device of claim 1, wherein a thickness of the extension is equal to or less than a thickness of an insulating layer of the RDL that the contact pad is located in.

11. The device of claim 1, wherein the semiconductor device is part of a computer having one or more electrical circuits that includes the redistribution layer of the semiconductor device.

12. A method of manufacturing a semiconductor device, comprising:
providing a first redistribution layer portion and forming a first array of through layer via TLV elements in the first redistribution layer portion, the TLV elements of the first redistribution layer portion arranged to carry one of first electrical signals, a power voltage connection or an electrical ground connection;
providing a second redistribution layer portion adjacent to the first redistribution layer, and forming a second array of the TLV elements in the second redistribution layer portion, the TLV elements of the second redistribution layer portion arranged to carry one of second electrical signals, the power voltage connection or the electrical ground connection, wherein:
for the TLV elements carrying the first electrical signals and the second electrical signals that are separated from each other by one or more of the TLV elements carrying the electrical ground connections, the forming of the first array and the forming of the second array includes forming one or more contact pads to have one or more extensions projecting therefrom into a null space between the one or more of TLV elements carrying the electrical ground connections and the TLV elements carrying the first electrical signal or the second electrical signal.

13. The method of claim 12, wherein the redistribution layer is part of an interposer layer, a package substrate layer or a printed circuit board layer of the semiconductor device.

14. The method of claim 12, wherein forming the redistribution layer includes forming a plurality of the redistribution layers.

15. The method of claim 12, wherein when the redistribution layer is an interposer layer or a package substrate layer, the one or more of the TLV elements carrying the electrical ground connections from device component contacts to the contact pads with the extensions contacting one or more of a front side dielectric layer a backside dielectric layer or a core layer of the interposer layer or the package substrate layer.

16. The method of claim 12, wherein when the redistribution layer is an PCB substrate layer, the one or more of the TLV elements carrying the electrical ground connections from backside contacts of an interposer layer or a package substrate layer to the contact pads with the extensions contacting one or more insulating layers of the PCB substrate layer.

17. The method of claim 12, the forming the extension includes forming the extension to be aligned with a circumference that is a λ/8 radial distance away from an aggressor signal carrying TLV element or a victim signal receiving element, wherein a signal wavelength, λ, is given by the formula:
$$λ = 300 / ( F \times ( {ε}_{R} ) 1 / 2 )$$
where F equals a frequency of signal transmission from the aggressor signal carrying TLV element 120a and εR equals an average dielectric constant of the redistribution layer.

18. The method of claim 12, wherein the forming of the extension includes forming the extension to have a length such that a tip of the extension that is centered in the null space.

19. The method of claim 12, wherein the forming of the extension includes forming the extension to have a width that is equal to or less than a diameter of the contact pad that the extension projects from.

20. The method of claim 12, wherein the forming of the extension includes forming the extension to have a thickness that is equal to or less than a thickness of an insulating layer of the RDL that the contact pad is located in.
